(19) United States
(12) Patent Application Publication
(10) Pub. No.: US 2008/0174396 A1
(43) Pub. Date: Jul. 24, 2008

(54) TRANSFORMERS AND BALUNS

(75) Inventors: Tae-Hoon CHOI, Suwon-si (KR); Chul-Ho CHUNG, Hwaseong-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 11/972,662

(22) Filed: Jan. 11, 2008

(30) Foreign Application Priority Data
Jan. 24, 2007 (KR) 10-2007-007528

(51) Int. Cl. H01F 27/28

(52) U.S. Cl. 336/182

(57) ABSTRACT

A transformer includes a primary coil assembly and a secondary coil assembly juxtaposed in a stack and which are electromagnetically inductively coupled and substantially symmetrical to one another. The primary coil assembly includes a plurality of primary coils coplanar with first insulation layers, respectively, and symmetrical to each other, and a first via unit connecting adjacent ones of the primary coils to each other. The secondary coil assembly includes a plurality of secondary coils coplanar with a plurality of second insulation layers, respectively, and symmetrical to each other, and a second via unit connecting adjacent ones of the secondary coils to each other.

### BACKGROUND OF THE INVENTION

1. Field of the Invention

The present invention relates to transformers and baluns. More particularly, the present invention relate to a transformer and to a balun that are employed in a system-on-chip (SOC).

2. Description of the Related Art

A system-on-chip (SOC) is an integrated circuit (IC) formed on a single chip. Previously, ICs were typically formed on boards and thereby formed what is commonly known as printed circuit boards (PCBs). An SOC, though, is much more compact than a PCB and may be readily assembled with other electronics. In general, semiconductor elements and radio-frequency (RF) circuit elements are formed on a single chip in an SOC, and an inductor or a transformer is formed on a semiconductor wiring which has already been formed on a substrate of the SOC. The transformer is confined to a small area so that the chip may have a high density, i.e., may be highly integrated. However, reducing the scale of the transformer compromises its characteristics such as inductance, a magnetic coupling ratio, etc.

A transformer is formed of two adjacent electromagnetically coupled inductors (coils), and aims to transfer signals from an input one of the coils to an output one of the coils with minimal loss. To this end, each inductor preferably has high inductance and the two inductors preferably have good symmetry and a high magnetic coupling ratio. However, as mentioned above, when such a transformer is formed in a small area so as to enhance the degree to which the chip is integrated, these charactericteristics of the transformer may be degraded. Thus, research has been focused on developing a transformer that is compact and yet offers good performance.

In this respect, a primary coil and a secondary coil of a transformer have been stacked in an attempt to minimize the area occupied by the transformer while realizing a relatively high magnetic coupling ratio between the primary coil and the secondary coil. Additionally, attempts have been made to increase the number of turns of the coils and thereby increase the inductance and the magnetic coupling ratio of the transformer. However, a compact transformer having high inductance, good symmetry and a high magnetic coupling ratio has not yet been developed.

A balun is a device similar to that of a transformer for converting between balanced lines or signals and unbalanced lines or signals. Accordingly, a balun that offers good performance will also have high inductance, will exhibit good symmetry and will have a high magnetic coupling ratio. However, like a transformer, a balun that is compact and yet has a high inductance, good symmetry and a high magnetic coupling ratio has yet to have been developed.

### SUMMARY OF THE INVENTION

An object of the present invention is to provide a transformer having good characteristics such as good symmetry, high inductance and a high magnetic coupling ratio.

Similarly, another object of the present invention is to provide a balun having good characteristics such as good symmetry, high inductance and a high magnetic coupling ratio.

According to one aspect of the present invention, the present invention provides a transformer/balun including a primary coil assembly and a secondary coil assembly juxtaposed in a stack and which are electromagnetically inductively coupled and substantially symmetrical to one another. The primary coil assembly includes a plurality of primary coils coplanar with first insulation layers, respectively, and symmetrical to each other, and a first via unit connecting adjacent ones of the primary coils to each other. The secondary coil assembly includes a plurality of secondary coils coplanar with a plurality of second insulation layers, respectively, and symmetrical to each other, and a second via unit connecting adjacent ones of the secondary coils to each other. Preferably, each of the primary and secondary coil assemblies has an even number of coils, respectively.

The first insulation layers may be juxtaposed all together with the second insulation layers. Alternatively, the first and second insulation layers may be alternately disposed in a stack.

Preferably, each primary and secondary coil has a spiral shape when viewed from above (in plan). In particular, each primary and secondary coil may have at least one turn, and each turn of the primary and secondary spiral portions may have a polygonal profile.

Also, the primary coil assembly may include four (stacked) primary coils, and the first via unit may include first, second and third vias. In this case, each primary coil may have a primary spiral portion having at least one turn and a primary connection portion located at one end of the primary spiral portion and connected to one of the first and third vias. The uppermost and lowermost primary coils in the stack may each have a primary terminal portion located at the other end of the primary spiral portion and through which external signals are applied to the transformer/balun. The central primary coils in the stack may include a primary coupling portion located at the other end of the primary spiral portion and connected to the second via.

Likewise, the secondary coil assembly may include four (stacked) secondary coils, and the second via unit may include fourth, fifth and sixth vias. In this case, each secondary coil may have a secondary spiral portion having at least one turn and a secondary connection portion located at one end of the secondary spiral portion and connected to one of the fourth and sixth vias. The uppermost and lowermost secondary coils in the stack of secondary coils may each include a secondary terminal portion located at the other end of the secondary spiral portion and from which signals are output from the transformer/balun. The central secondary coils may include a secondary coupling portion located at the other end of the secondary spiral portion and connected to the fifth via.

According to still another aspect of the present invention, the transformer/balun may further include a substrate on which the insulation layers are stacked, and a shield layer interposed between the insulation layers and the substrate for preventing energy from leaking into the substrate from the coils. Preferably, the shield layer is a (patterned) layer of conductive material.

According to another aspect of the present invention, the present invention provides a balun including a primary coil assembly and a secondary coil assembly juxtaposed in a stack and which are electromagnetically inductively coupled and substantially symmetrical to one another, and a tap for grounding the secondary coil assembly. The primary coil assembly includes a plurality of primary coils coplanar with first insulation layers, respectively, and symmetrical to each other, and a first via unit connecting adjacent ones of the primary coils to each other. The secondary coil assembly includes a plurality of secondary coils coplanar with a plurality of second insulation layers, respectively, and symmetrical to each other, and a second via unit connecting adjacent ones of the secondary coils to each other. Preferably, each of the primary and secondary coil assemblies has an even number of coils, respectively. Each primary coil of the transformer and balun may have a primary spiral portion having at least one turn and a primary connection portion located at one end of the primary spiral portion and connected to the first via unit. The uppermost and lowermost primary coils may each include a primary terminal portion that is formed at the other end of the primary spiral portion and at which external signals are applied to the transformer/balun. Likewise, each secondary coil may have a secondary spiral portion having at least one turn and a secondary connection portion located at one end of the secondary spiral portion and connected to the second via unit. The uppermost and lowermost secondary coils may each have a secondary terminal portion formed at the other end of the secondary spiral portion and from which signals are output from the transformer/balun.

According to another aspect of the present invention, at least one each of the primary coils and the secondary coils of the transformer/balun consists of a strip of electrically conductive material extending entirely along an upper surface of a respective one of the insulation layers. Thus, the coils overall may be spaced relatively close together.

According to still yet another aspect of the present invention, at least one each of the primary and secondary coils of the transformer/balun includes an upper coil part extending along the upper surface of one of the insulation layers, a lower coil part, and a plug extending through the insulation layer and into contact with the primary upper and lower coil parts. Thus, such coils can provice a relatively high electromagnetic inductance.

A transformer or a balun according to the present invention has good symmetry. Additionally, the transformer or the balun may have high inductance by providing the coils thereof with large numbers of turns or by making the insulation layers and hence, the coils, relatively thick in the case in which the coils have an upper coil part, a lower coil part and a plug extending through an insulation into contact with the upper and lower coil parts. Furthermore, the transformer or the balun can have a high magnetic coupling ratio especially in the case in which primary and secondary coils thereof each consist of a strip of electrically conductive material whose width is substantially greater than its thickness, whereby the coils can be disposed relatively close together.

### BRIEF DESCRIPTION OF THE DRAWINGS

The above and other features and advantages of the present invention will become more apparent from the following detailed description of the preferred embodiments thereof made with reference to the accompanying drawings, in which:

FIG. 1A is a perspective of the coils of a first embodiment of a transformer in accordance with the present invention;

FIG. 1B is a cross-sectional view of the first embodiment of the transformer taken in the same direction as line I-I′ in FIG. 1A;

FIGS. 2A and 2B are top views of primary coils of the first embodiment of the transformer in accordance with the present invention;

FIGS. 2C and 2D are top views of secondary coils the first embodiment of the transformer in accordance with the present invention;

FIG. 3A is a perspective view of the coils of a second embodiment of a transformer in accordance with the present invention;

FIG. 3B is a cross-sectional view of the second embodiment of the transformer taken in the same direction as line II-II′ in FIG. 3A;

FIGS. 4A and 4C are top views of primary coils of the second embodiment of the transformer in accordance with the present invention;

FIGS. 4B and 4D are top views of secondary coils of the second embodiment of the transformer in accordance with the present invention;

FIG. 5 is a perspective view of the coils of a third embodiment of a transformer in accordance with the present invention;

FIGS. 6A to 6D are top views of primary coils of the third embodiment of the transformer in accordance with the present invention;

FIGS. 6E to 6H are top views of secondary coils of the third embodiment of the transformer in accordance with the present invention;

FIG. 7 is a perspective view of the coils of a fourth embodiment of a transformer in accordance with the present invention;

FIGS. 8A to 8D are top views of primary coils of the fourth embodiment of the transformer in accordance with the present invention;

FIGS. 8E to 8H are top views of secondary coils of the fourth embodiment of the transformer in accordance with the present invention;

FIG. 9 is a cross-sectional view of a fifth embodiment of a transformer in accordance with the present invention; and

FIG. 10 is a perspective view of coils of a balun in accordance with the present invention.

### DETAILED DESCRIPTION OF THE PREFERRED EMBODIMENTS

The present invention will be described more fully hereinafter with reference to the accompanying drawings. Those numerals which are the same in different drawings designate like elements. Also, in the drawings, the sizes and relative sizes of layers and regions may be exaggerated for clarity.

Furthermore, when an element or layer is referred to as being disposed “on,” another element or layer, such a description includes the case in which the element or layer is disposed directly on the other element or layer as well as the case in which another element(s) or layer(s) is/are present therebetween. Likewise, when an element is referred to as being “connected to” or “coupled to” another element, such a description includes the case in which the element is directly connected or coupled to the other element as well as the case in which another element(s) is/are coupled or connected therebetween.

Terms, such as “beneath,” “below,” “lower,” “above,” “upper” and the like, may be used herein to describe the spacial relationship between one element (or feature) and another as illustrated in the figures. However, the element(s) or feature(s) may assume other spacial relationships in actual use depending on the orientation of the device with which they are integrated. Thus, it will be understood that the terms used in the specification, such as “beneath,” “below,” “lower,” “above,” “upper” and the like are relative terms used for ease of description only and thus, are not limiting in their own right.

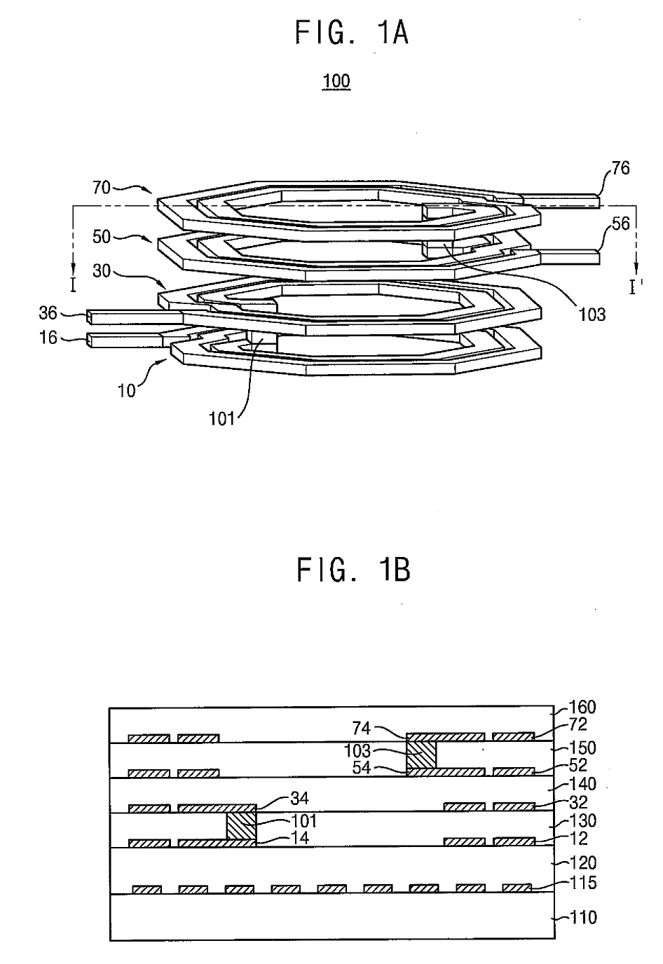

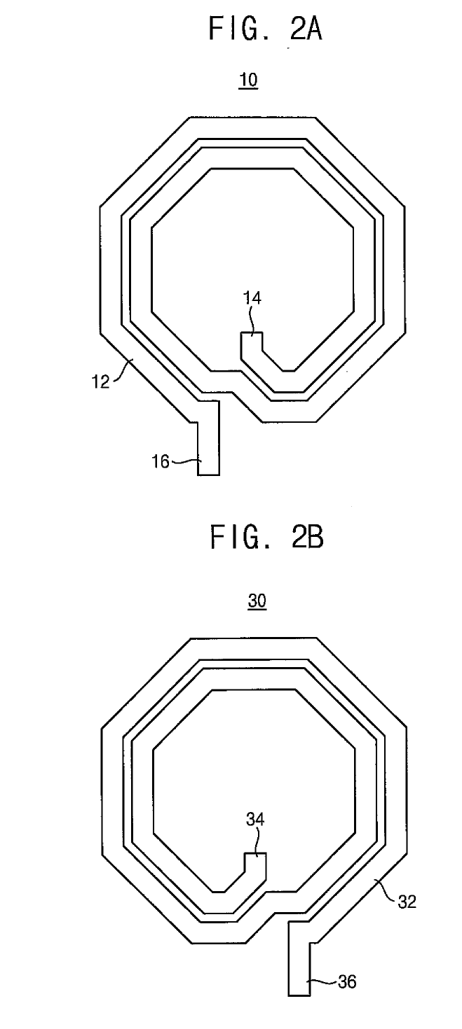

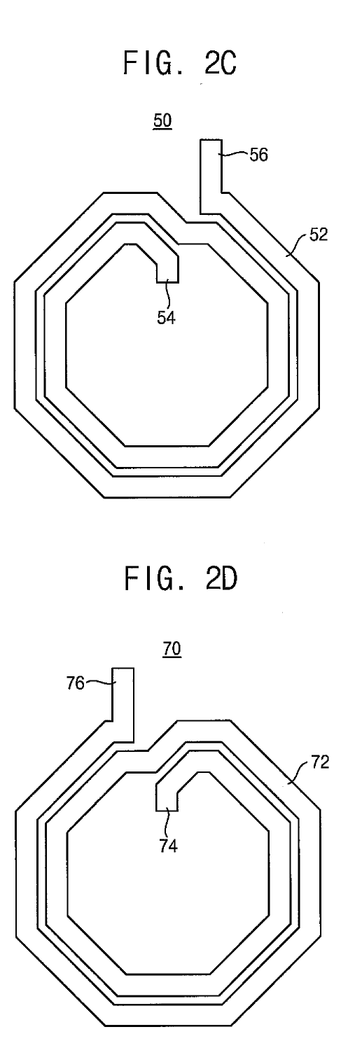

A first embodiment of a transformer 100 in accordance with the present invention will now be described with reference to FIGS. 1A to 1B and 2A to 2D. Note, for clarity a semiconductor substrate and insulation layers of the transformer are not shown in FIG. 1A. The transformer 100 includes a first primary coil 10, a second primary coil 30, a first secondary coil 50, a second secondary coil 70, a primary via 101, and a secondary via 103. The first and second primary coils 10 and 30 together with the primary via 101 constitute a primary coil assembly, and the first and second secondary coils 50 and 70 together with the secondary via 103 constitute a secondary coil assembly. The primary via 101 and the secondary via 103 constitute a first via unit.

The first and second primary coils 10 and 30 and the first and second secondary coils 50 and 70 are each generally planar and are formed on (extend along) first, second, third and fourth insulation layers 120, 130, 140 and 150, respectively so as to be coplanar with the insulation layers. The insulation layers 120, 130, 140 and 150 are disposed on a substrate 110. The substrate 110 may be of a type which is used in semiconductor devices. A fifth insulation layer 160 may be formed on the fourth insulation layer 150 to cover the second secondary coil 70, so that the second secondary coil 70 will be electrically insulated. The transformer 100 may also include a shield layer 115 of electrically conductive material (patterned) on the substrate 110. The shield layer 115 prevents energy from the first transformer 100 from leaking into the substrate 110.

The first primary coil 10 has a first primary spiral portion 12, a first primary connection portion 14 and a first primary terminal portion 16. The first primary spiral portion 12, the first primary connection portion 14 and the first primary terminal portion 16 comprise electrically conductive material. Also, the first primary spiral portion 12 has at least one turn, and may have the form of a strip whose length is larger than its width. Also, the thickness of the first primary spiral portion 12 is smaller than the width of the strip. In the embodiment shown in FIG. 2A, the radius of the first primary spiral portion 12 decreases in a clockwise direction as viewed from above (in plan). Alternatively, though, the radius of the first primary spiral portion 12 may decrease in a counter-clockwise direction.

Also, in the first embodiment of the present invention, the profile of each turn of the first primary spiral portion 12 when viewed from above is substantially that of a regular polygon, such as a regular octagon, a regular hexagon, a regular dodecagon, etc. (i.e., the profile is that of a regular polygon with the exception of angular portions that enable the spiral portion 12 to progress radially inwardly at the end of each turn). Thus, the first primary spiral portion 12 may be symmetrical about a center point (the geometrical center around which the spiral portion constantly moves while constantly approaching or receding from the point). Alternatively, each turn of the first primary spiral portion 12 may have a substantially circular profile when viewed from above (again, a circular profile except for those portions that enable the spiral portion 12 to progress radially inwardly at the end of each turn).

The first primary connection portion 14 is located at a first end of the first primary spiral portion 12, and contacts the primary via 101 connecting the first and second primary coils 10 and 30 to each other. The first end may be that of the first primary spiral portion 12 which is closest to the (geometrical) center of the first primary spiral portion 12. In the present embodiment, the first primary connection portion 14 has the form of a strip that extends perpendicularly to and from a side of the first primary spiral portion 12. In addition, the shape of a second primary connection portion 34 of the second primary coil 30, which will be described later, may be substantially the same as that of the first primary connection portion 14.

The first primary terminal portion 16 is located at a second end of the first primary spiral portion 12, and may receive external signals. The second end may be that of the first primary spiral portion 12 which is furthest from the (geometrical) center of the first primary spiral portion 12. In the present embodiment, the first primary terminal portion 16 extends parallel to the first primary connection portion 14 and to the left of the first primary connection portion 14 when viewed from above. Alternatively, the first primary terminal portion 16 may be disposed to the right of the first primary connection portion 14 when viewed from above.

The second primary coil 30 has a second primary spiral portion 32, a second primary connection portion 34 and a second primary terminal portion 36. The second primary spiral portion 32, the second primary connection portion 34 and the second primary terminal portion 36 comprise electrically conductive material.

The shape of the second primary coil 30 is substantially the same as that of the first primary coil 10 (the exceptions being that the second primary coil 30 extends spirally in a direction counter to that of the first primary coil 10, and the location of the second primary terminal portion 36 relative to the second primary connection portion 34 is opposite to that of the location of the first primary terminal portion 16 relative to the first primary connection portion 14 when viewed from above). Also, the spiral portions of the first and second primary coils 10 and 30 are disposed coaxially (a line extending perpendicular to the planes in which the the first and second primary coils 10 and 30 lie passes through the geometrical centers of the first primary spiral portion 12 and the second primary spiral portion 32). Thus, the first and second primary coils 10 and 30, which contact the ends of the first primary via 101, respectively, are symmetrical to each other with respect to an imaginary line extending in the longitudinal direction of (i.e., parallel to) and intermediate the first primary connection portion 14 and the second primary connection portion 34.

As was mentioned above, the first and second primary coils 10 and 30 are connected to each other through the first primary via 101. The primary via 101 extends through the second insulation layer 130 and contacts the first and second primary connection portions 14 and 34. The first primary via 101 comprises conductive material.

The first secondary coil 50 has a first secondary spiral portion 52, a first secondary connection portion 54 and a first secondary terminal portion 56. The first secondary spiral portion 52, the first secondary connection portion 54 and the first secondary terminal portion 56 comprise electrically conductive material.

In the illustrated embodiment, the first secondary coil 50 has the same shape as the first primary coil 10 but rotated by 180 degrees about the geometrical center of the first primary spiral portion 12 as viewed from above. Also, the spiral portions of the first secondary coil 50 and the first primary coil 10 are disposed coaxially. Thus, the first secondary coil 50 and the first primary coil 10 are symmetrical to each other about an intermediate point on an axis extending between the (geometrical) center of the first primary spiral portion 12 and the (geometrical) center of the first secondary spiral portion 52. Alternatively, the first secondary coil 50 may have the same shape as the second primary spiral portion 32 but rotated by 180 degrees about the geometrical center of the as viewed from above. Thus, the first secondary coil 50 and the second primary coil 30 may be symmetrical to each other about an intermediate point on an axis extending between the center of the second primary spiral portion 32 and the center of the first secondary spiral portion 52.

The first secondary terminal portion 56 may be used to output signals from the first secondary coil 50.

The second secondary coil 70 includes a second secondary spiral portion 72, a second secondary connection portion 74 and a second secondary terminal portion 76. The second secondary spiral portion 72, the second secondary connection portion 74 and the second secondary terminal portion 76 comprise electrically conductive material.

In the illustrated embodiment, the second secondary coil 70 has the same shape as the second primary coil 30 but rotated by 180 degrees with respect to the (geometrical) center of the second primary spiral portion 32. Also, the spiral portions of the second secondary coil 70 and the second primary coil 30 are disposed coaxially. Thus, the second secondary coil 70 and the second primary coil 30 are symmetrical to each other about an intermediate point on an axis extending between the (geometrical) center of the second primary spiral portion 32 and the (geometrical) center of the second secondary spiral portion 72). Alternatively, the second secondary coil 70 may have the same shape as the first primary coil 10 but rotated by 180 degrees with respect to the (geometrical) center of the first primary spiral portion 12. Thus, the second secondary coil 70 and the first primary coil 10 may be symmetrical to each other about an intermediate point on an axis extending between the (geometrical) center of the first primary spiral portion 12 and the (geometrical) center of the second secondary spiral portion 72.

The second secondary terminal portion 76 may be used to output signals from the second secondary coil 70.

The first and second secondary coils 50 and 70 are connected to each other through the secondary via 103. The secondary via 103 extends through the fourth insulation layer 150 and contacts the first and second secondary connection portions 54 and 74. The secondary via 103 comprises conductive material.

As described above, the first and second primary coils 10 and 30 of the primary coil assembly exhibit substantial line symmetry with respect to each other, and the first and second secondary coils 50 and 70 of the secondary coil assembly exhibit substantial line symmetry with respect to each other. On the other hand, the first primary coil 10 and the first secondary coil 50 exhibit substantial point symmetry with respect to each other, and the second primary coil 30 and the second secondary coil 70 also exhibit substantial point symmetry with respect to each other. Alternatively, the first primary coil 10 and the second secondary coil 70 may exhibit substantial point symmetry with respect to each other, and the second primary coil 30 and the first secondary coil 50 may also exhibit substantial point symmetry with respect symmetrical to each other. Thus, the primary coil assembly (made up of the first and second primary coils 10 and 30 together with the first primary via 101) may as a whole exhibit substantial point symmetry with respect to the secondary coil assembly (made up of the first and second secondary coils 50 and 70 together with the first secondary via 103).

Accordingly, the first embodiment of the transformer 100 in accordance with the present invention exhibits a high degree of symmetry.

In addition, the inductance of the first embodiment of the transformer 100 corresponds to the number of turns of the spiral portions 12, 32, 52 and 72, respectively. It is relatively easy to form the spiral portions 12, 32, 52 and 72 with a large number of turns because each of the spiral portions 12, 32, 52 and 72 is formed on the upper surface of a single insulation layer. Thus, it is relatively easy according to the present invention to provide a transformer having high inductance. Furthermore, the first embodiment of the transformer 100 according to the present invention may have a high magnetic coupling ratio because the coils 10, 30, 50 and 70 may be disposed close to each other (stacked vertically close to each other) because each of the the coils 10, 30, 50 and 70 is relatively thin (has a thickness that is significantly less than its width).

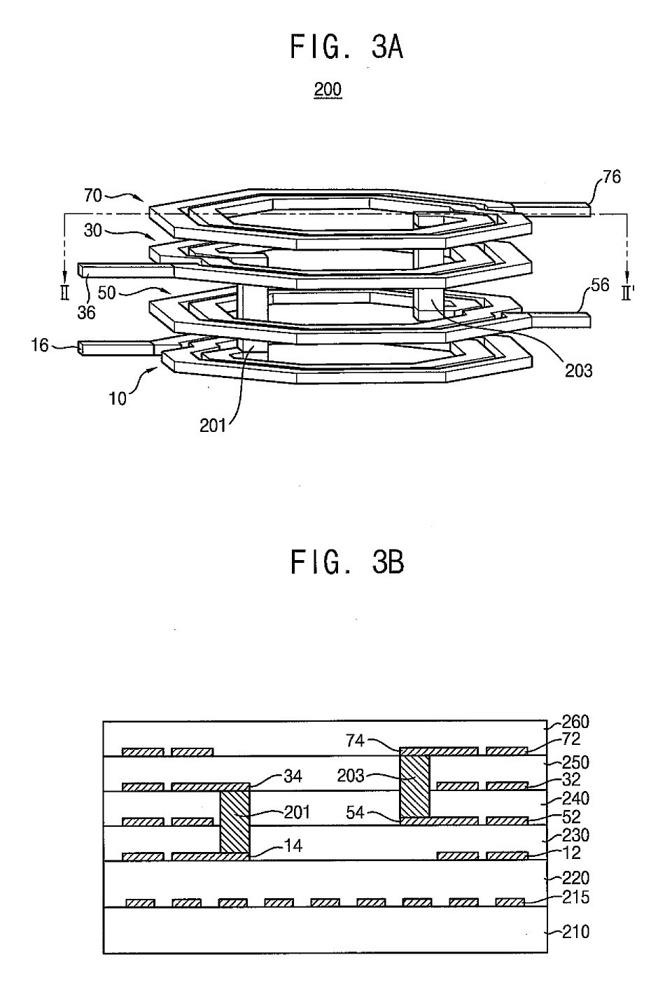

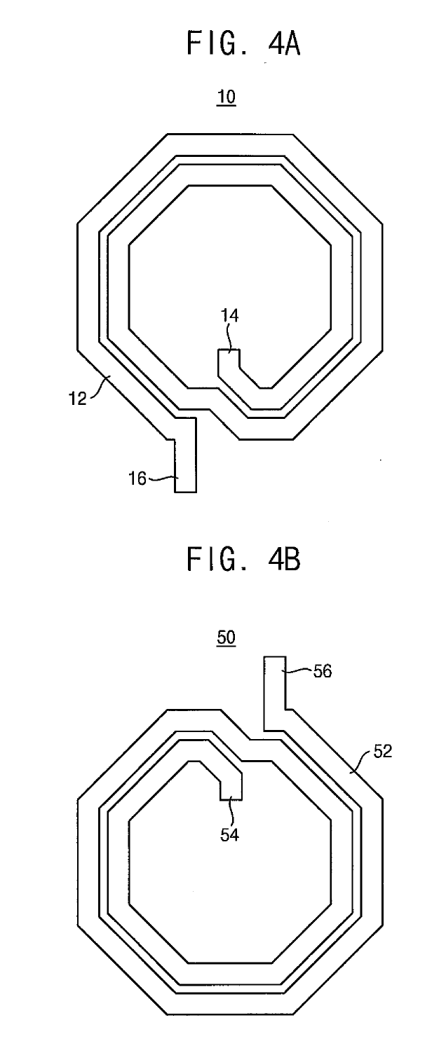

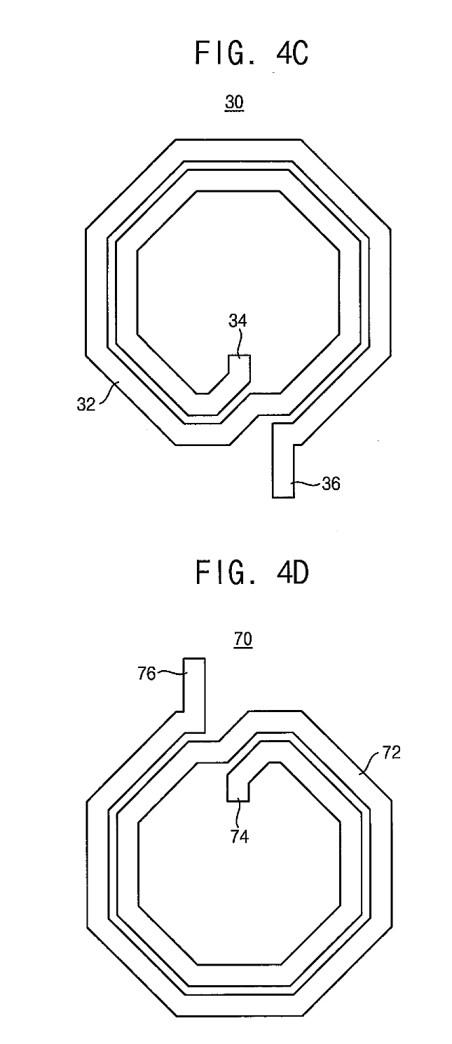

A second embodiment of a transformer 200 in accordance with the present invention will now be described with reference to FIGS. 3A to 3B and 4A to 4D. The transformer 200 includes a first primary coil 10, a second primary coil 30, a first secondary coil 50, a second secondary coil 70, a primary via 201, and a secondary via 203. The first and second primary coils 10 and 30 together with the primary via 201 constitute a primary coil assembly, and the first and second secondary coils 50 and 70 together with the secondary via 203 constitute a secondary coil assembly. The primary via 201 and the secondary via 203 constitute a second via unit.

The first primary coil 10, the first secondary coil 50, the second primary coil 30 and second secondary coil 70 are formed on first, second, third and fourth insulation layers 220, 230, 240 and 250, respectively. The insulation layers 220, 230, 240 and 250 are disposed on a substrate 210. The substrate 210 may be of a type which is used in semiconductor devices. A fifth insulation layer 260 may be formed on the fourth insulation layer 250 to cover the second secondary coil 70, so that the second secondary coil 70 is electrically insulated. The transformer 200 may also include a shield layer 215 of electrically conductive material on the substrate 210. The shield layer 215 prevents energy from the first transformer 200 from leaking into the substrate 210.

As shown best in FIG. 3A, amongst the coils of the transformer 200, the second primary coil 30 is disposed immediately over the first secondary coil 50 unlike the first embodiment of the transformer 100. The primary via 201 connecting the first and second primary coils 10 and 30 extends through the second and third insulation layers 230 and 240, and the secondary via 203 connecting the first and second secondary coils 50 and 70 extends through the third and fourth insulation layers 240 and 250.

The second embodiment of the transformer 200 is otherwise substantially the same as the first embodiment of the transformer 100. Thus, the first and second primary coils 10 and 30 of the primary coil assembly exhibit substantial line symmetry with respect to each other, and the first and second secondary coils 50 and 70 of the secondary coil assembly also exhibit substantial line symmetry with respect to each other.

Additionally, the first primary coil 10 and the first secondary coil 50 exhibit substantial point symmetry with respect to each other, and the second primary coil 30 and the second secondary coil 70 exhibit substantial point symmetry with respect to each other. Alternatively, though, the first primary coil 10 and the second secondary coil 70 may exhibit substantial point symmetry with respect to each other, while the second primary coil 30 and the first secondary coil 50 exhibit substantial point symmetry with respect to each other. Thus, the primary coil assembly (made up of the first and second primary coils 10 and 30 together with the primary via 201) may exhibit substantial point symmetry as a whole to the secondary coil assembly (made up of the first and second secondary coils 50 and 70 together with the secondary via 203).

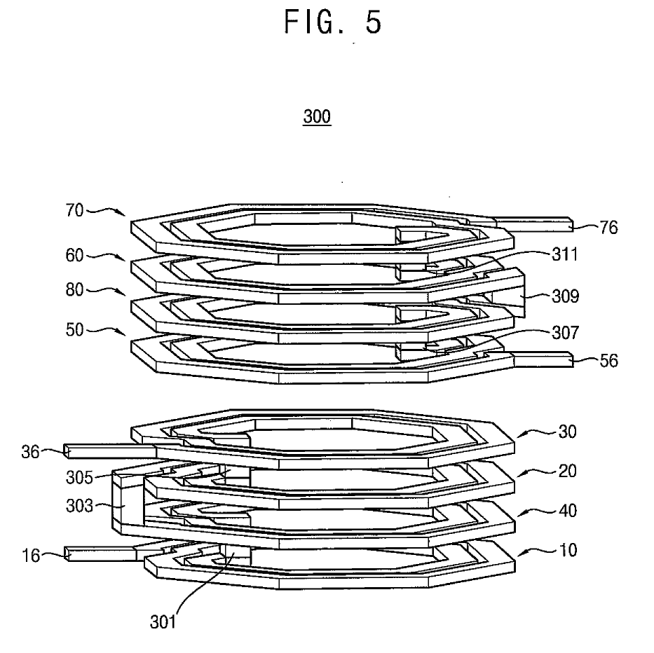

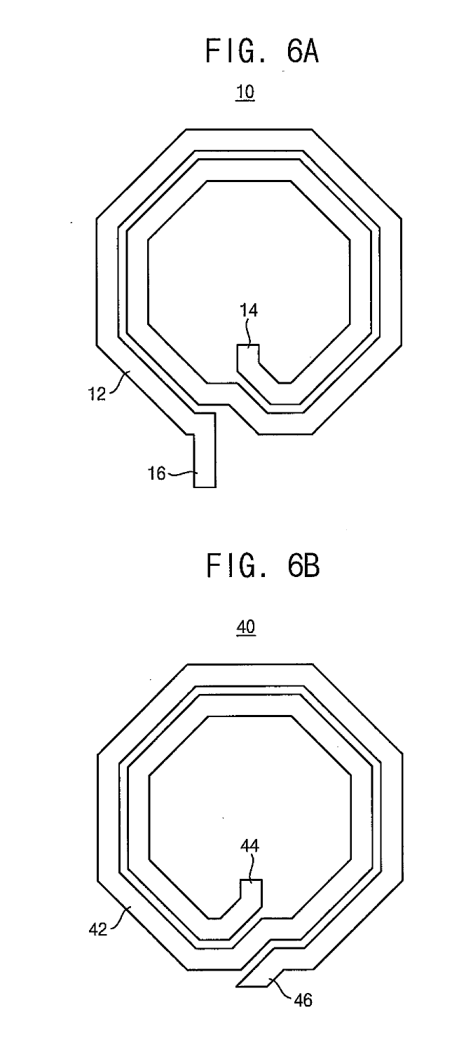

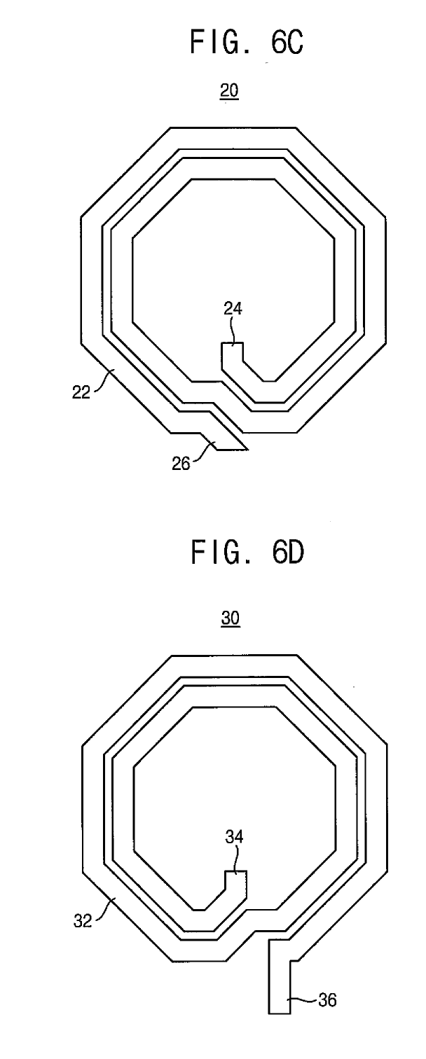

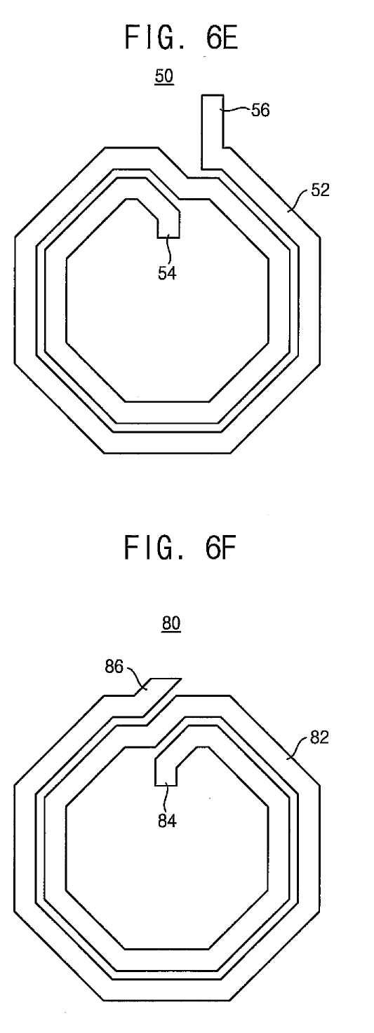

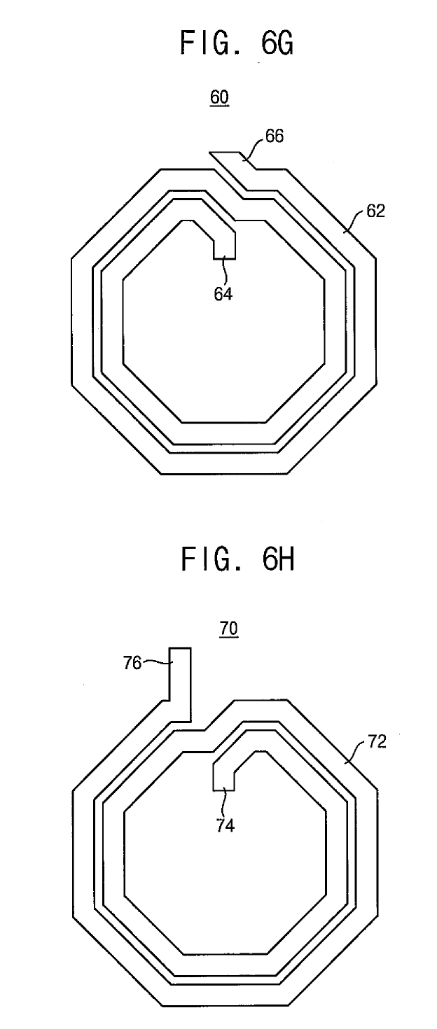

A third embodiment of a transformer 300 in accordance with the present invention will now be described with reference to FIGS. 5 and 6A to 6H. The transformer 300 includes a first primary coil 10, a second primary coil 30, a third primary coil 20, a fourth primary coil 40, a first secondary coil 50, a second secondary coil 70, a third secondary coil 60, a fourth secondary coil 80, a first primary via 301, a second primary via 303, a third primary via 305, a first secondary via 307, a second secondary via 309 and a third secondary via 311. The first to fourth primary coils 10, 30, 20 and 40 together with the first to third primary vias 301, 303 and 305 constitute a primary coil assembly, and the first to fourth secondary coils 50, 70, 60 and 80 together with the first to third secondary vias 307, 309 and 311 constitute a secondary coil assembly. The first to third primary vias 301, 303 and 305 together with the first to third secondary vias 307, 309 and 311 constitute a via unit.

The coils 10, 40, 20, 30, 50, 80, 60 and 70, like those of the previous embodiments, are formed on respective insulation layers. In addition, another insulation layer may be provided over the coil 70 so as to cover the coil 70 and thereby electrically insulate the coil 70. Furthermore, the insulation layers are disposed on a substrate, and a shielding layer may be formed on the substrate.

In the third third embodiment of the transformer 300 according to the present invention, each of the primary and secondary coil assemblies includes four stacked coils. That is, the primary coil assembly includes the first primary coil 10, the fourth primary coil 40, the third primary coil 20 and the second primary coil 30, and the secondary coil assembly includes the first secondary coil 50, the fourth secondary coil 80, the third secondary coil 60 and the second secondary coil 70.

The first primary via 301 extends between the first primary coil 10 and the fourth primary coil 40, the second primary via 303 extends between the fourth primary coil 40 and the third primary coil 20, and the third primary via 305 extends between the third primary coil 20 and the second primary coil 30. Thus, the first to fourth primary coils 10, 30, 20 and 40 are connected to one another by the first primary via 301, the second primary via 303, and the third primary via 305.

The shape and orientation of third primary coil 20 are substantially the same as those of the first primary coil 10, the exception being that the third primary coil 20 includes a first primary coupling portion 26 instead of a terminal portion. That is, the third primary coil 20 includes a third primary spiral portion 22, a third primary connection portion 24 and a first primary coupling portion 26. The third primary connection portion 24 is connected to the second primary connection portion 34 of the second primary coil 30 by the third primary via 305.

The shape and orientation of the fourth primary coil 40 are substantially the same as those of the second primary coil 30, the exception being that the fourth primary coil 40 includes a second primary coupling portion 46 instead of a terminal portion. That is, the fourth primary coil 40 includes a fourth primary spiral portion 42, a fourth primary connection portion 44 and a second primary coupling portion 46. The fourth primary connection portion 44 is connected to the first primary connection portion 14 of the first primary coil 10 by the first primary via 301.

Furthermore, as shown in the figures, the first and second primary coils 10 and 30 exhibit substantial line symmetry with respect to each other, and the third and fourth primary coils 20 and 40 also exhibit substantial line symmetry with respect to each other.

The first and second primary coupling portions 26 and 46 are connected to each other through the second primary via 303. In the illustrated embodiment, the second primary via 303 extends perpendicularly to and between a side of the regular polygon formed by a turn of the third primary spiral portion 22 and a side of the polygon formed by a turn of the fourth primary spiral portion 42. Thus, a first structure made up of the first and fourth primary coils 10 and 40 together with the first primary via 301 exhibits substantial line symmetry with respect to a second structure made up of the third and second primary coils 20 and 30 together with the third primary via 305.

More specifically, the first primary coil 10 disposed at the lowermost part of the primary coil assembly exhibits substantial line symmetry with respect to the second primary coil 30 disposed at the uppermost part of the primary coil assembly, and the fourth and third primary coils 40 and 20 exhibit substantial line symmetry with respect to each other. Thus, the first and second structures exhibit substantial line symmetry with respect to each other.

The first secondary via 307 extends between the first secondary coil 50 and the fourth secondary coil 80, the second secondary via 309 extends between the fourth secondary coil 80 and the third secondary coil 60, and the third secondary via 311 extends between the third secondary coil 60 and the second secondary coil 70. Thus, the first to fourth secondary coils 50, 80, 60 and 70 are connected to one another by the first secondary via 307, the second secondary via 309, and the third secondary via 311.

The shape and orientation of the third secondary coil 60 are substantially the same as those of the first secondary coil 50, the exception being that the third secondary coil 60 includes a first secondary coupling portion 66 instead of a terminal portion. That is, the third secondary coil 60 includes a third secondary spiral portion 62, a third secondary connection portion 64 and a first secondary coupling portion 66. The third secondary connection portion 64 is connected to the second secondary connection portion 74 of the second secondary coil 70 by the third secondary via 311.

The shape and orientation of the fourth secondary coil 80 are substantially the same as those of the second secondary coil 70, the exception being that the fourth secondary coil 80 includes a second secondary coupling portion 86 instead of a terminal portion. That is, the fourth secondary coil 80 includes a fourth secondary spiral portion 82, a fourth secondary connection portion 84 and a second secondary coupling portion 86. The fourth secondary connection portion 84 is connected to the first secondary connection portion 54 of the first secondary coil 50 by the first secondary via 307.

As illustrated in the drawings, the first and second secondary coils 50 and 70 exhibit substantial line symmetry with respect to each other. Also, the third and fourth secondary coils 60 and 80 exhibit substantial line symmetry with respect to each other.

The first and second secondary coupling portions 66 and 86 are connected to each other by the second secondary via 309. In the illustrated embodiment, the second secondary via 309 extends perpendicularly to and between a side of the regular polygon formed by a turn of the third secondary spiral portion 62 and a side of the regular polygon formed by the fourth secondary spiral portion 82. Thus, a third structure made up of the first and fourth secondary coils 50 and 80 together with the first secondary via 307 exhibits substantial line symmetry with respect to a fourth structure made up of the third and second secondary coils 60 and 70 together with the third secondary via 311.

More specifically, the first secondary coil 50 disposed at the lowermost part of the third secondary coil assembly exhibits substantial line symmetry with respect to the second secondary coil 70 disposed at the uppermost part of the third secondary coil assembly, and the fourth and third secondary coils 80 and 60 exhibit substantial line symmetry with respect to each other. Thus, the third and fourth structures exhibit substantial line symmetry with respect to each other.

As described above, in the third embodiment of a transformer 300 in accordance with the present invention, the first and second structures made up of respective portions of the primary coil assembly exhibit substantial line symmetry with respect to each other, and the third and fourth structures made up of respective portions of the secondary coil assembly exhibit substantial line symmetry with respect to each other. Furthermore, the primary coil assembly and the secondary coil assembly exhibit substantial point symmetry with respect to each other. In particular, the first primary coil 10 and the first secondary coil 50 exhibit substantial point symmetry with respect to each other, the fourth primary coil 40 and the fourth secondary coil 80 exhibit substantial point symmetry with respect to to each other, the third primary coil 20 and the third primary coil 60 exhibit substantial point symmetry with respect to each other, and the second primary coil 30 and the second secondary coil 70 exhibit substantial point symmetry with respect to each other. Thus, the primary coil assembly and the secondary coil assembly exhibit substantial point symmetry with respect to to each other.

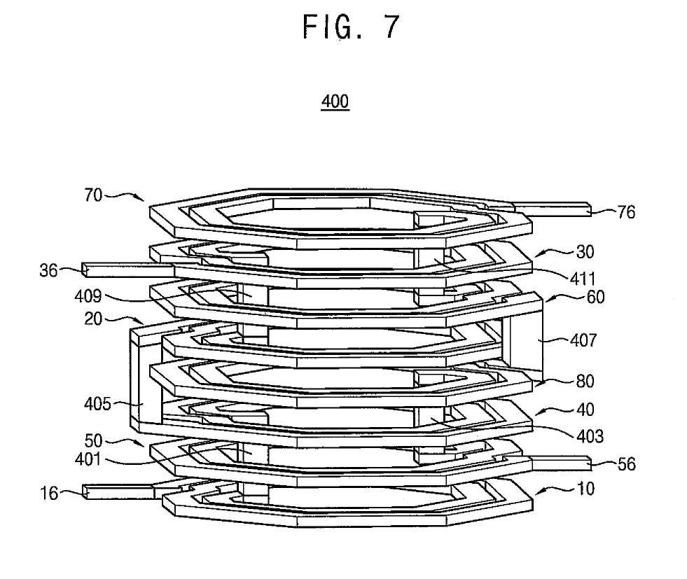

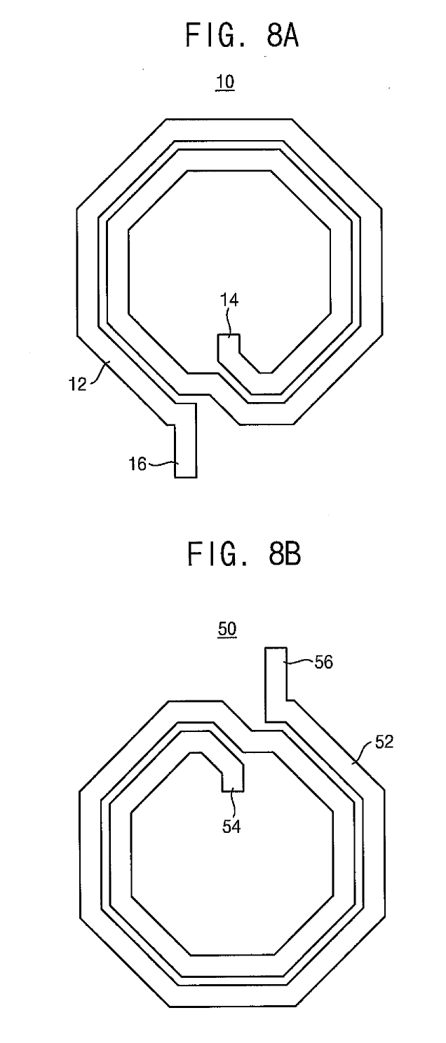

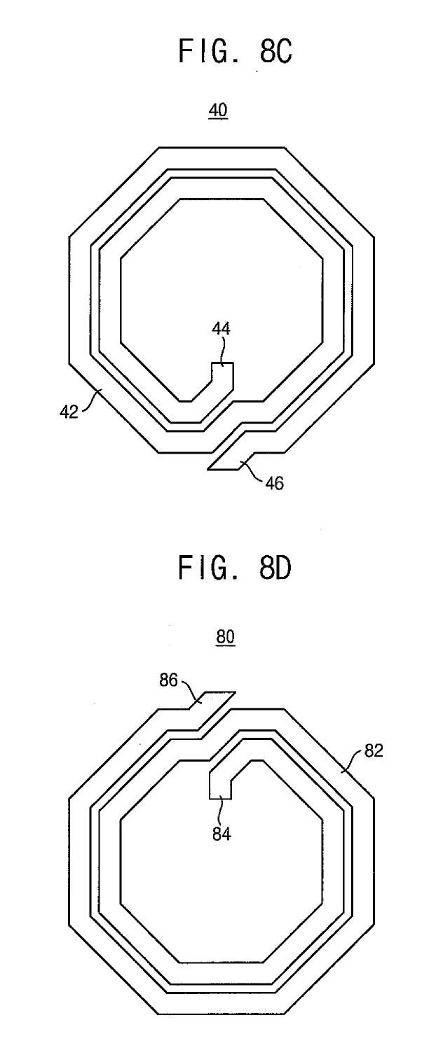

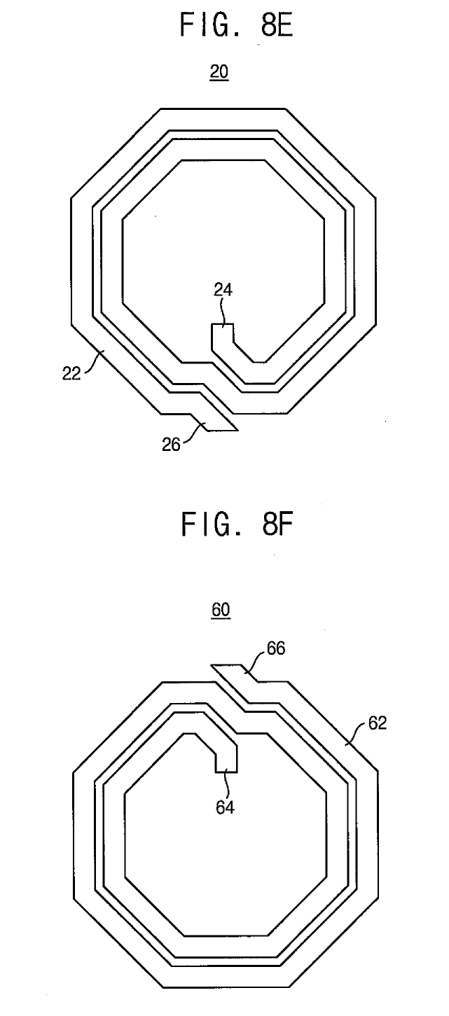

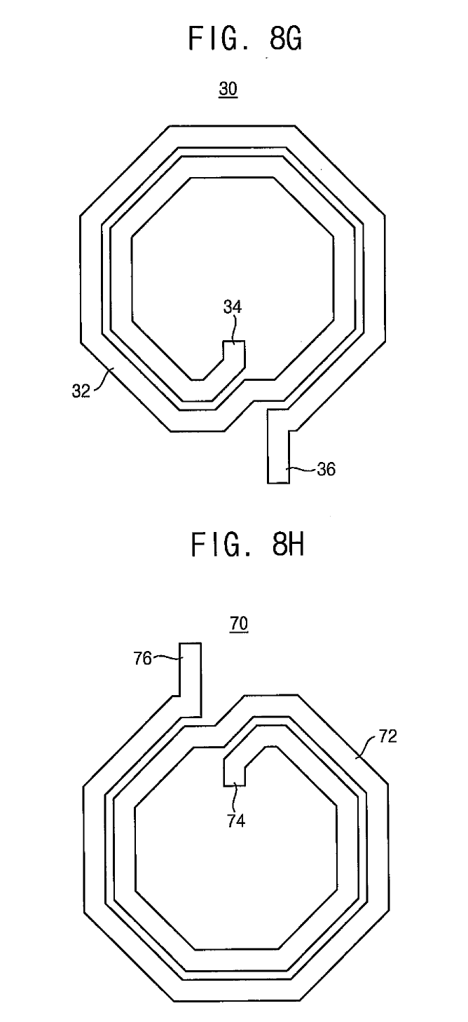

A fourth embodiment of a transformer 400 in accordance with the present invention will now be described with reference to FIGS. 7 and 8A to 8H. The transformer 400 includes a first primary coil 10, a second primary coil 30, a third primary coil 20, a fourth primary coil 40, a first secondary coil 50, a second secondary coil 70, a third secondary coil 60, a fourth secondary coil 80, a first primary via 401, a second primary via 403, a third primary via 405, a first secondary via 407, a second secondary via 409 and a third secondary via 411. The first to fourth primary coils 10, 30, 20 and 40 together with the first to third primary vias 401, 403 and 405 constitute a primary coil assembly, and the first to fourth secondary coils 50, 70, 60 and 80 together with the first to third secondary vias 407, 409 and 411 constitute a secondary coil assembly. The first to third primary vias 401, 403 and 405 together with the first to third secondary 407, 409 and 411 constitute a via unit.

The coils 10, 50, 40, 80, 20, 60, 30 and 70, like those of the previous embodiments, are formed on respective insulation layers. In addition, another insulation layer may be provided over the coil 70 so as to cover the coil 70 and thereby electrically insulate the coil 70. Furthermore, the insulation layers are disposed on a substrate, and a shielding layer may be formed on the substrate.

However, unlike the third embodiment of the transformer 300 in which the stack of primary coils 10, 40, 20 and 30 is disposed under the stack secondary coils 50, 80, 80 and 70, in the fourth embodiment of the transformer 400, the primary coils 10, 40, 20 and 30 and the secondary coils 50, 80, 60 and 70 are alternately disposed in a stack. Specifically, the first primary coil 10, the first secondary coil 50, the fourth primary coil 40, the fourth secondary coil 80, the third primary coil 20, the third secondary coil 60, the second primary coil 30 and the second secondary coil 70 are disposed in the foregoing sequence one atop the other. Otherwise, the fourth embodiment of the transformer 400 is substantially the same as the third embodiment of the transformer 300. Thus, the fourth embodiment of the transformer 400 exhibits symmetries substantially the same as those of the third embodiment of the transformer 300 according to the present invention.

Each of the embodiments of a transformer according to the present invention has been described above as comprising a primary coil assembly and a secondary coil assembly having only two or four coils each. However, the present invention is not so limited; rather, the primary coil assembly and the secondary coil assembly may each have other numbers of coils. When the primary coil assembly and the secondary coil assembly each has an even number of coils, not only is each of the primary coil assembly and the secondary coil assembly substantially symmetrical, but the primary coil assembly and the secondary coil assembly are also substantially symmetrical with respect to each other.

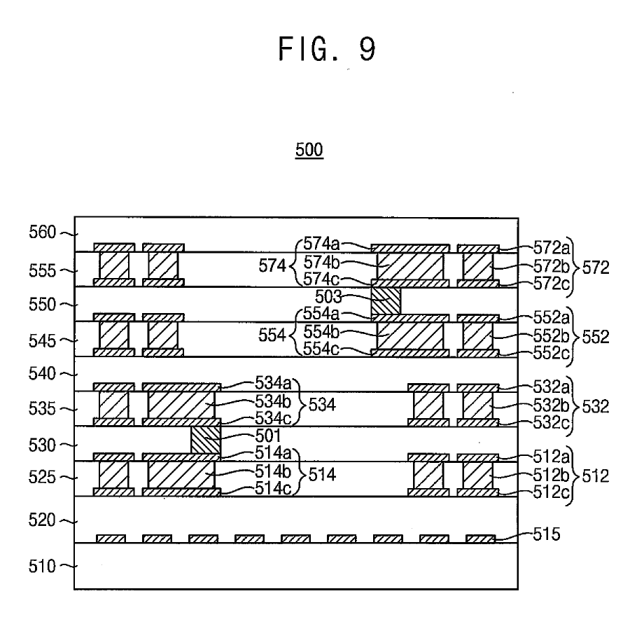

A fifth embodiment of a transformer 500 in accordance with the present invention will now be described with reference to FIG. 9. The transformer 500 includes a first primary coil, a second primary coil, a first secondary coil, a second secondary coil, a primary via 501, and a secondary via 503.

The fifth embodiment of the transformer 500 is similar to those of the previously described embodiments and, in particular, to the first embodiment of the transformer 100 shown in FIGS. 1A-2D, with the following exception. In each of the previously described embodiments, each of the coils of the transformer lies only along the upper surface of an insulation layer. On the other hand, in the fifth embodiment of the transformer 500 according to the present invention, each of the coils of the transformer has an upper coil section formed on an upper insulation layer, a lower coil section formed on a lower insulation layer and a conductive plug extending through the upper insulation layer and connecting the upper and lower coil sections to each other. Thus, each coil also extends coplanar with the insulation layers and in particular, with the upper insulation layer through which the plug of the coil extends.

More specifically, the first primary coil includes a first primary spiral portion 512, a first primary connection portion 514 and a first primary terminal portion (not shown). The first primary spiral portion 512 has a first primary upper spiral part 512a, a first primary lower spiral part 512c and a first primary plug section 512b. The first primary connection portion 514 has a first primary upper connector 514a, a first primary lower connector 514c and a second primary plug section 514b. The first primary terminal portion has a first primary upper terminal (not shown), a first primary lower terminal (not shown) and a third primary plug section (not shown). Similarly, the second primary coil includes a second primary spiral portion 532, a second primary connection portion 534 and a second primary terminal portion (not shown). The second primary spiral portion 532 has a second primary upper spiral part 532a, a second primary lower spiral part 532c and a fourth primary plug section 532b. The second primary connection portion 534 has a second primary upper connector 534a, a second primary lower connector 534c and a fifth primary plug section 534b. The second primary terminal portion has a second primary upper terminal (not shown), a second primary lower terminal (not shown) and a sixth primary plug section (not shown).

In addition, the first secondary coil includes a first secondary spiral portion 552, a first secondary connection portion 554 and a first secondary terminal portion (not shown). The first secondary spiral portion 552 has a first secondary upper spiral part 552a, a first secondary lower spiral part 552c and a first secondary plug section 552b. The first secondary connection portion 554 has a first secondary upper connector 554a, a first secondary lower connector 554c and a second secondary plug section 554b. The first secondary terminal portion has a first secondary upper terminal (not shown), a first secondary lower terminal (not shown) and a third secondary plug section (not shown). Likewise, the second secondary coil includes a second secondary spiral portion 572, a second secondary connection portion 574 and a second secondary terminal portion (not shown). The second secondary spiral portion 572 has a second secondary upper spiral part 572a, a second secondary lower spiral part 572c and a fourth secondary plug section 572b. The second secondary connection portion 574 has a second secondary upper connector 574a, a second secondary lower connector 574c and a fifth secondary plug section 574b. The second secondary terminal portion has a second secondary upper terminal (not shown), a second secondary lower terminal (not shown) and a sixth secondary plug section (not shown).

A primary lower coil section made up of the first primary lower spiral 512c, the first primary lower connector 514c and the first primary lower terminal is formed on a first lower insulation layer 520. In addition, a primary upper coil section made up of the first primary upper spiral 512a, the first primary upper connector 514a and the first primary upper terminal is formed on a first upper insulation layer 525. The first and second primary plug sections 512b and 514b and the third primary plug section extend through the first upper insulation layer 525.

The second primary coil, the first secondary coil and the second secondary coil each have a structure substantially the same as that of the first primary coil.

As described above, each coil of the transformer 500 has an upper coil section, a lower coil section and a conductive plug. Therefore, the inductance of the fifth embodiment of a transformer 500 according to the present invention will be higher than that of a corresponding transformer of the previous embodiments, e.g., the first embodiment of the transformer 100 shown in FIGS. 1A-2D. Also, according to this embodiment of the present invention, the inductance of the transformer is proportional to the thickness of its conductive plugs, i.e., to the thickness of the insulation layers through which the conductive plugs extend. Therefore, it is relatively easy to fabricate a transformer having a high design inductance by forming the insulation layers to thicknesses determined in advance to yield a transformer having the desired high inductance.

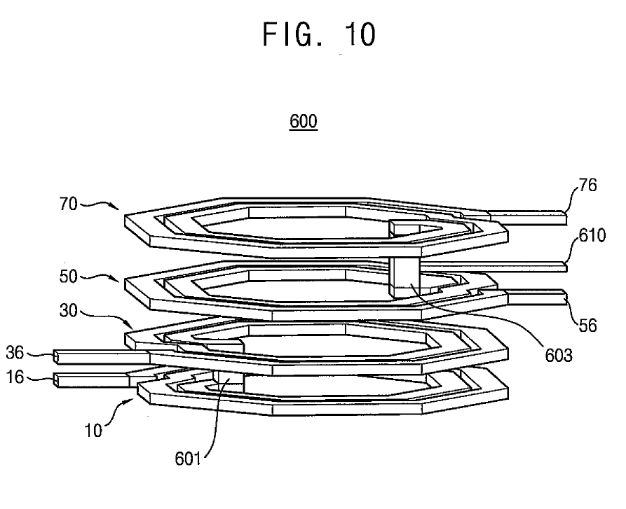

A balun 600 in accordance with the present invention will now be described with reference to FIG. 10. The balun 600 includes a first primary coil 10, a second primary coil 30, a first secondary coil 50 and a second secondary coil 70, a primary via 601 and a secondary via 603. The first and second primary coils 10 and 30 together with the primary via 601 constitute a primary coil assembly, and the first and second secondary coils 50 and 70 together with the secondary via 603 constitute a secondary coil assembly. The primary and secondary vias 601 and 603 constitute a via unit.

The balun 600 is similar to that of the first embodiment of the transformer 100 but includes a tap 610. The tap 610 extends from the secondary via 603 and is grounded. The first and second secondary coils 50 and 70 exhibit substantial line symmetry with respect to each other. Accordingly, the balun 600 may convert applied unbalanced signals to balanced signals and output the balanced signals.

According to embodiments of the present invention, a transformer or balun includes a primary coil assembly and a secondary coil assembly, each of which has coils which are symmetrical to each other, and which assemblies are symmetrical to each other as well. Additionally, a transformer or balun according to the present invention may comprise coils each having a large number of turns or each having an upper coil part, a lower coil part and a plug. Thus, a transformer or balun having high inductance can be realized according to the present invention. Furthermore, according to embodiments of the present invention, the coils of the transformer or the balun are stacked, and each coil may have a thickness smaller than its width. Thus, the primary coils and secondary coils may be spaced close to one another. Accordingly, a transformer or balun having a high magnetic coupling ratio can be realized according to the present invention.

Finally, although the present invention has been described in connection with the preferred embodiments thereof, it is to be understood that the scope of the present invention is not so limited. On the contrary, various modifications of and changes to the preferred embodiments will be apparent to those of ordinary skill in the art. Thus, changes to and modifications of the preferred embodiments may fall within the true spirit and scope of the invention as defined by the appended claims.

What is claimed is:

1. A transformer or balun comprising:
a plurality of electrically insulative layers disposed one atop the other, the insulative layers including a plurality of first insulation layers, and a plurality of second insulation layers,
a primary coil assembly including a plurality of primary coils and a first via unit, the primary coils being coplanar with the first insulation layers, the primary coils exhibiting substantial symmetry with respect to each other, and the first via unit connecting adjacent ones of the primary coils to each other; and
a secondary coil assembly including a plurality of secondary coils and a second via unit, the secondary coils being coplanar with the second insulation layers, the secondary coils exhibiting substantial symmetry with respect to each other, and the second via unit connecting adjacent ones of the secondary coils to each other, and
wherein the primary and secondary coil assemblies are juxtaposed in a stack, are electromagnetically inductively coupled to each other, and are substantially symmetrical to each other.

2. The transformer or balun of claim 1, wherein each of the primary coils has a primary spiral portion having at least one turn, and a primary connection portion located at one end of the primary spiral portion and disposed in contact with the first via unit, and each of an uppermost and a lowermost one of the primary coils has a primary terminal portion located at the other end of the primary spiral portion thereof and dedicated to receive external signals applied to the transformer or balun.

3. The transformer or balun of claim 1, wherein each of the secondary coils has a secondary spiral portion having at least one turn, and a secondary connection portion located at one end of the secondary spiral portion thereof and disposed in contact with the second via unit, and each of uppermost and lowermost ones of the secondary coils has a secondary terminal portion located at the other end of the secondary spiral portion thereof and dedicated to output signals from the transformer or balun.

4. The transformer or balun of claim 1, wherein the first insulation layers are all together juxtaposed relative to the second insulation layers.

5. The transformer or balun of claim 1, wherein the first and second insulation layers are disposed alternately in a stack.

6. The transformer or balun of claim 1, wherein each of the primary and secondary coils has a spiral portion when viewed in plan.

7. The transformer or balun of claim 6, wherein each turn of each of the spiral portions of the primary and secondary coils has a polygonal profile.

8. The transformer or balun of claim 1, wherein the total number of coils of each of the primary and secondary coil assemblies is an even number.

9. The transformer or balun of claim 8, wherein the primary coil assembly includes four primary coils, and the first via unit includes first, second and third vias,
each of the primary coils has a primary spiral portion having at least one turn and a primary connection portion located at one end of the primary spiral portion thereof and disposed in contact with one of the first and third vias,
each of an uppermost and a lowermost one of the primary coils includes a primary terminal portion that is located at the other end of the primary spiral portion thereof and is dedicated to receive external signals applied to the transformer or balun, and
each of two central coils of the primary coils, interposed between the uppermost and lowermost ones of the primary coils, includes a primary coupling portion located at the other end of the primary spiral portion thereof and disposed in contact with the second via.

10. The transformer or balun of claim 8, wherein the secondary coil assembly includes four secondary coils, and the second via unit includes fourth, fifth and sixth vias,
each of the secondary coils has a secondary spiral portion having at least one turn and a secondary connection portion located at one end of the secondary spiral portion thereof and connected to one of the fourth and sixth vias,
each of an uppermost and a lowermost one of the secondary coils includes a secondary terminal portion that is located at the other end of the secondary spiral portion thereof and is dedicated to output signals from the transformer or balun, and
each of two central coils of the secondary coils, interposed between the uppermost and lowermost ones of the secondary coils, includes a secondary coupling portion located at the other end of the secondary spiral portion thereof and connected to the fifth via.

11. The transformer or balun of claim 1, wherein at least one each of the primary coils and the secondary coils consists of a strip of electrically conductive material extending entirely along an upper surface of a respective one of the insulation layers, each of the primary coils having a primary spiral portion having at least one turn, and a primary connection portion located at one end of the primary spiral portion and disposed in contact with the first via unit, each of the secondary coils having a secondary spiral portion having at least one turn, and a secondary connection portion located at one end of the secondary spiral portion thereof and disposed in contact with the second via unit, and each of the strips of electrically conductive material constituting one of the primary and secondary coils having a width that is substantially greater than the thickness thereof.

12. The transformer or balun of claim 1, wherein at least one each of the primary and secondary coils includes an upper coil part extending along an upper surface of one of the insulation layers, a lower coil part, and a plug extending through said one of the insulation layers into contact with the upper and lower coil parts.

13. The transformer or balun of claim 1, further comprising a substrate on which the first and second insulation layers are disposed, and a shield layer that prevents energy from the coils from leaking into the substrate, the shield layer being interposed between the first and second insulation layers and the substrate.

14. The transformer of claim 13, wherein the shield layer includes a layer of electrically conductive material.

15. A balun comprising:
a plurality of electrically insulative layers disposed one atop the other, the insulative layers including a plurality of first insulation layers, and a plurality of second insulation layers,
a primary coil assembly including a plurality of primary coils and a first via unit, the primary coils be coplanar with the first insulation layers, the primary coils exhibiting substantial symmetry with respect to each other, and the first via unit connecting adjacent ones of the primary coils to each other; and
a secondary coil assembly including a plurality of secondary coils and a second via unit, the secondary coils being coplanar with the second insulation layers, the secondary coils exhibiting substantial symmetry with respect to each other, and the second via unit connecting adjacent ones of the secondary coils to each other,
wherein the primary and secondary coil assemblies are juxtaposed in a stack, are electromagnetically inductively coupled to each other, and are substantially symmetrical to each other; and
a tap providing a ground for the second via unit.

16. The balun of claim 15, wherein each of the primary coils has a primary spiral portion having at least one turn, and a primary connection portion located at one end of the primary spiral portion and disposed in contact with the first via unit, and each of an uppermost and a lowermost one of the primary coils has a primary terminal portion located at the other end of the primary spiral portion thereof and dedicated to receive external signals applied to the balun.

17. The balun of claim 15, wherein each of the secondary coils has a secondary spiral portion having at least one turn, and a secondary connection portion located at one end of the secondary spiral portion thereof and disposed in contact with the second via unit, and each of uppermost and lowermost ones of the secondary coils has a secondary terminal portion located at the other end of the secondary spiral portion thereof and dedicated to output signals from the balun.

18. The balun of claim 17, wherein the tap extends from the second via unit.

19. The balun of claim 15, wherein at least one each of the primary coils and the secondary coils consists of a strip of electrically conductive material extending entirely along an upper surface of a respective one of the insulation layers, each of the primary coils having a primary spiral portion having at least one turn, and a primary connection portion located at one end of the primary spiral portion and disposed in contact with the first via unit, each of the secondary coils having a secondary spiral portion having at least one turn, and a secondary connection portion located at one end of the secondary spiral portion thereof and disposed in contact with the second via unit, and each of the strips of electrically conductive material constituting one of the primary and secondary coils having a width that is substantially greater than the thickness thereof.

20. The balun of claim 15, wherein at least one each of the primary and secondary coils includes an upper coil part extending along an upper surface of one of the insulation layers, a lower coil part, and a plug extending through said one of the insulation layers into contact with the upper and lower coil parts.
